(19) United States
(12) Patent Application Publication
(10) Pub. No.: US 2026/0305110 A1
(43) Pub. Date: Oct. 1, 2026

(54) DISPLAY DEVICE AND METHOD OF MANUFACTURING THE SAME

(71) Applicant: LG Display Co., Ltd., Seoul (KR)

(72) Inventors: Geon Hyeong KIM, Paju-si (KR); Ji Ho SON, Paju-si (KR); Ho Yoon JUNG, Paju-si (KR)

(73) Assignee: LG Display Co., Ltd., Seoul (KR)

(21) Appl. No.: 19/404,775

(22) Filed: Dec. 1, 2025

(30) Foreign Application Priority Data
Mar. 31, 2025 (KR) 10-2025-0041625

(51) Int. Cl. H10K 59/38; H10K 59/12; H10K 59/80; H10K 102/00

(52) U.S. Cl. CPC H10K 59/38; H10K 59/1201; H10K 59/871; H10K 2102/311

(57) ABSTRACT

Disclosed is a display device including a display panel layer configured to display an image and a cover layer located on the display panel layer, wherein the cover layer includes a color control layer having a color for controlling a color tone appearing on the display panel layer to target color coordinates.

### CROSS-REFERENCE TO RELATED APPLICATION(S)

This application claims the benefit of Korean Patent Application No. 10-2025-0041625, filed on Mar. 31, 2025, which is hereby incorporated by reference as if fully set forth herein.

### BACKGROUND

### Technical Field

The present disclosure relates to a display device and a method of manufacturing the same.

### Description of the Related Art

As information technology advances, the market for display devices, which are the medium of connection between users and information, is growing. Accordingly, the use of display devices, such as a light emitting display device (LED), a quantum dot display device (QDD), and a liquid crystal display device (LCD), is increasing.

Each of the display devices includes a display panel including subpixels, a drive unit configured to output a drive signal for driving the display panel, and a power supply unit configured to generate power to be supplied to the display panel or the drive unit.

Each of the display devices may be configured such that, when drive signals, such as scan signals and data signals, are supplied to the subpixels formed on the display panel, the selected subpixels transmit light or emit light directly, thereby displaying an image.

### BRIEF SUMMARY

Embodiments of the present disclosure remedy the problems arising from the color tone (hue) of a display panel layer shifting in one direction. Embodiments of the present disclosure easily control/tune the target color coordinates of the display panel layer even when a polarizer is not included. Embodiments of the present disclosure prevent or minimize light leakage at the edges of layers constituting a display panel and minimize surface delamination that may occur at the edges of the layers constituting the display panel.

A display device according to an embodiment of the present disclosure includes a display panel layer configured to display an image and a cover layer located on the display panel layer, wherein the cover layer includes a color control layer having a color for controlling a color tone appearing on the display panel layer to target color coordinates.

The color control layer may include a pigment exhibiting a second color different from a first color corresponding to the color tone.

The color control layer may include a resin and a pigment.

The cover layer may include a film layer located on the display panel layer and the color control layer located on the film layer.

The cover layer may include a glass layer located on the display panel layer, the color control layer located on the glass layer, and a resin layer located on the color control layer.

The glass layer may have a smaller area than the color control layer.

The color control layer may cover an upper surface and a side surface of the glass layer.

The cover layer may further include a black frame layer located between the display panel layer and the glass layer, the black frame layer having a frame shape that exposes an active area of the display panel layer.

The display panel layer may include a subpixel having at least one of a circular opening, an oval opening, and a polygonal opening.

The color control layer may have a color for controlling the color tone appearing on the display panel layer in a display off state.

A display device according to another embodiment of the present disclosure includes a display panel layer configured to display an image and a cover layer located on the display panel layer, wherein the color control layer comprises a resin and a pigment.

A method of manufacturing a display device according to another embodiment of the present disclosure includes forming a display panel layer configured to display an image, forming a color control layer having a color for controlling a color tone appearing on the display panel layer to target color coordinates, and forming a cover layer including the color control layer on the display panel layer.

The color control layer may include a pigment exhibiting a second color different from a first color corresponding to the color tone.

The step of forming the color control layer may include adding a material that exhibits a color to a resin.

### BRIEF DESCRIPTION OF THE SEVERAL VIEWS OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a block diagram schematically showing the light emitting display device;

FIGS. 2 and 3 are views illustrating the configuration of a gate-in-panel type gate drive unit;

FIG. 4 is a first example view showing the section of a display panel according to a first embodiment;

FIG. 5 is a second example view showing the section of the display panel according to the first embodiment;

FIG. 6 is a view illustrating a method of configuring a color control layer;

FIG. 7 is a view illustrating a color coordinate control method using the color control layer;

FIG. 8 is a first example view showing the pixel structure of a display panel according to a second embodiment;

FIG. 9 is a second example view showing the pixel structure of the display panel according to the second embodiment;

FIG. 10 is an example view showing the physical characteristics of the display panel shown in FIG. 8;

FIG. 11 is a sectional view taken along line A1-A2 of FIG. 8 according to a first example;

FIG. 12 is a sectional view taken along line A1-A2 of FIG. 8 according to a second example;

FIG. 13 is a sectional view taken along line A1-A2 of FIG. 8 according to a third example;

FIG. 14 is a sectional view taken along line A1-A2 of FIG. 8 according to a fourth example;

FIG. 15 is an example view showing the color coordinates of a cover layer including a color control layer;

FIG. 16 is an example view showing the color coordinates of a cover layer including a color control layer; and

FIG. 17 is a view showing a light emitting display device according to a comparative example and a light emitting display device according to an example for comparison.

### DETAILED DESCRIPTION

A display device according to the present disclosure may be implemented as a television, a video player, a personal computer (PC), a home theater, an automotive electrical apparatus, or a smartphone; however, the present disclosure is not limited thereto. The display device according to the present disclosure may be implemented as a light emitting display device (LED), a quantum dot display device (QDD), and a liquid crystal display device (LCD). However, hereinafter, a light emitting display device that directly emits light based on an inorganic light emitting diode or an organic light emitting diode will be described by way of example, for the sake of convenience.

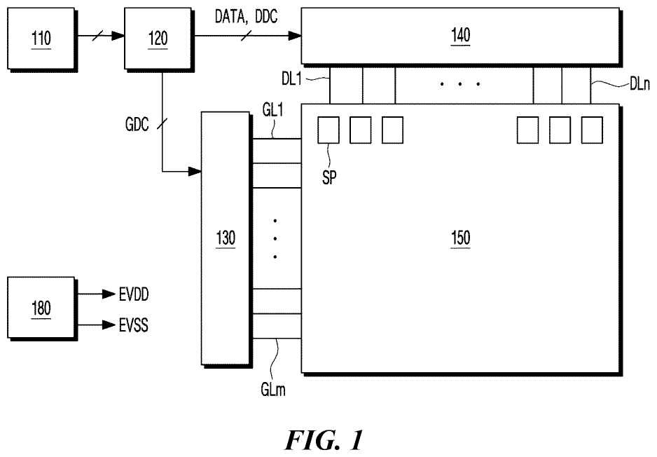

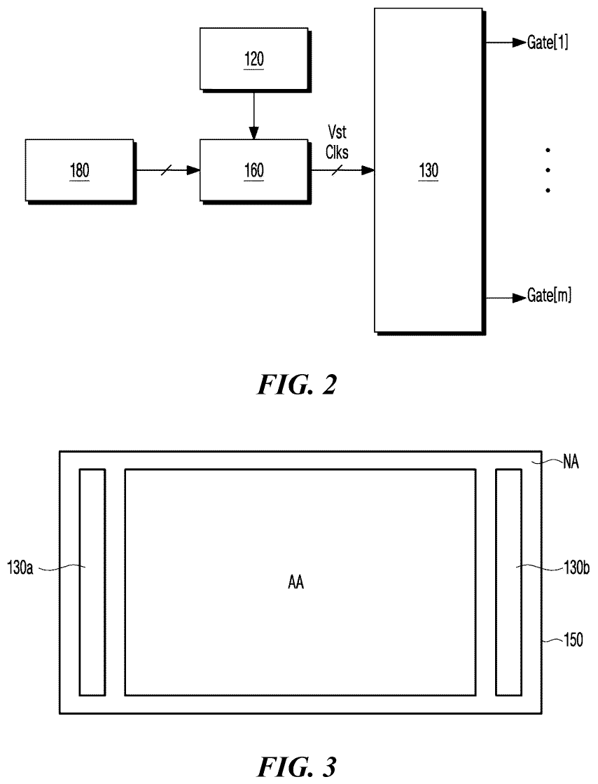

FIG. 1 is a block diagram schematically showing the light emitting display device, and FIGS. 2 and 3 are views illustrating the configuration of a gate-in-panel type gate drive unit.

As shown in FIGS. 1 to 3, the light emitting display device includes a timing controller (timing control circuit) 120, a gate drive unit (gate drive circuit) 130, a data drive unit (data drive circuit) 140, a display panel 150, and a power supply unit (power supply circuit) 180.

An image supply unit (set or host system) 110 may output various drive signals along with an image data signal supplied from the outside or stored in an internal memory. The image supply unit 110 may supply the data signal and the various drive signals to the timing controller 120.

The timing controller 120 can output a gate timing control signal GDC for controlling the operation timing of the gate drive unit 130, a data timing control signal DDC for controlling the operation timing of the data drive unit 140, and various synchronization signals (a vertical synchronization signal Vsync and a horizontal synchronization signal Hsync).

The timing controller 120 may supply the data signal DATA supplied from the image supply unit 110 to the data drive unit 140 along with the data timing control signal DDC. The timing controller 120 may be formed as an integrated circuit (IC) and mounted on a printed circuit board; however, the present disclosure is not limited thereto.

The gate drive unit 130 may output a gate signal in response to the gate timing control signal GDC supplied from the timing controller 120. The gate drive unit 130 may supply the gate signal to subpixels included in the display panel 150 via gate lines GL1 to GLm.

The gate drive unit 130 may be formed as an IC or directly on the display panel 150 using a gate-in-panel (GIP) method; however, the present disclosure is not limited thereto. However, hereinafter, a gate-in-panel type gate drive unit shown in FIGS. 2 and 3 will be described by way of example, for convenience of description.

The gate drive unit 130 may include shift registers 130a and 130b. The shift registers 130a and 130b may be formed as thin films on a non-active area NA of the display panel 150 using the gate-in-panel method. The gate drive unit 130 may output gate signals Gate[1] to Gate[m] for turning on or off a transistor formed in an active area AA of the display panel 150.

The gate drive unit 130 may operate based on signals and voltages output from the timing controller 120, the power supply unit 180, and a level shifter 160. The level shifter 160 may generate gate control signals required to drive the gate drive unit 130 (130a and 130b) based on the signals and the voltages output from the timing controller 120 and the power supply unit 180.

The data drive unit 140 may sample and latch the data signal DATA in response to the data timing control signal DDC supplied from the timing controller 120, and may convert a digital data signal into an analog data voltage based on a gamma reference voltage and output the same.

The data driving unit 140 may supply a data voltage to the subpixels included in the display panel 150 via data lines DL1 to DLn. The data driving unit 140 may be formed as an IC and mounted on the display panel 150 or on a printed circuit board; however, the present disclosure is not limited thereto.

The power supply unit 180 may generate a high-potential voltage and a low-potential voltage based on an external input voltage supplied from outside, and may output the same through a high-potential voltage line EVDD and a low-potential voltage line EVSS. The power supply unit 180 may generate and output the voltage required to drive the gate drive unit 130 or the voltage required to drive the data drive unit 140 in addition to the high-potential voltage and low-potential voltage.

The display panel 150 may be manufactured using a substrate having rigidity or flexibility, such as glass, silicon, or polyimide. The display panel 150 may include a plurality of subpixels SP configured to display an image. The subpixels SP may directly emit light in a direction toward an upper substrate, a lower substrate, or the upper substrate and the lower substrate of the display panel 150.

Each subpixel SP may emit one of red, green, blue, and white. The display panel 150 may display an image based on a pixel including a red subpixel, a green subpixel, and a blue subpixel or a pixel including a red subpixel, a green subpixel, a blue subpixel, and a white subpixel.

Meanwhile, in the above, the timing controller 120, the gate drive unit 130, and the data drive unit 140 has been described as separate components. However, depending on a method of implementing the light emitting display device, one or more of the timing controller 120, the gate drive unit 130, and the data drive unit 140 may be integrated into a single IC.

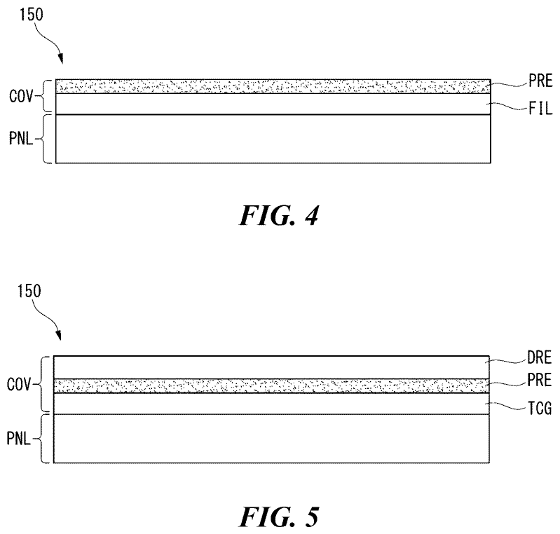

FIG. 4 is a first example view showing the section of a display panel according to a first embodiment, and FIG. 5 is a second example view showing the section of the display panel according to the first embodiment.

As shown in FIGS. 4 and 5, according to the first embodiment, the display panel 150 may include a display panel layer PNL including elements configured to display an image and a cover layer COV including a structure configured to protect the display panel layer PNL.

As shown in FIG. 4, the cover layer COV may include a film layer FIL and a color control layer PRE. For example, the film layer FIL may be made of a transparent film such as polyethylene terephthalate (PET) or polyimide (PI) and may have a thickness of about 100 μm; however, the present disclosure is not limited thereto. For example, the color control layer PRE may include a resin and a pigment (or a material capable of imparting color, such as a dye), and may have a thickness of about 10 to 20 μm; however, the present disclosure is not limited thereto.

As shown in FIG. 5, the cover layer COV may include a glass layer TCG, a color control layer PRE, and a resin layer DRE. For example, the glass layer TCG may include glass and may have a thickness of about 90 μm; however, the present disclosure is not limited thereto. For example, the color control layer PRE may include a resin (which may be referred to as a primer resin or a first resin layer) and a pigment (or a dye) and may have a thickness of about 10 μm; however, the present disclosure is not limited thereto. For example, the resin layer DRE may include a resin (which may be referred to as a damping resin or a second resin layer) and may have a thickness of about 60 μm; however, the present disclosure is not limited thereto.

Meanwhile, the cover layer COV may have an anti-reflective layer formed on an upper surface thereof by coating; however, the present disclosure is not limited thereto.

The color control layer PRE may be defined as a tuning layer capable of controlling/tuning problems arising from color tone (hue) shift in one direction in a display off state (including a display on state in some cases) of the display panel layer PNL. Here, the display off state refers to a non-display state where the display panel layer PNL does not display an image. The display panel layer PNL may exhibit color tone (hue) shift in one direction due to structural characteristics of the subpixels, for example. For a more detailed description related to this, refer to a second embodiment.

The color control layer PRE may be defined as a means configured to match target color coordinates (target color coordinates as seen when viewing the display panel layer through an optical system) such that a user's preferred color tone (hue) can be implemented on the display panel layer PNL. The color control layer PRE may be defined as an auxiliary optical compensation means that operates secondarily after primary electrical or physical optical compensation for the display panel layer PNL has been performed.

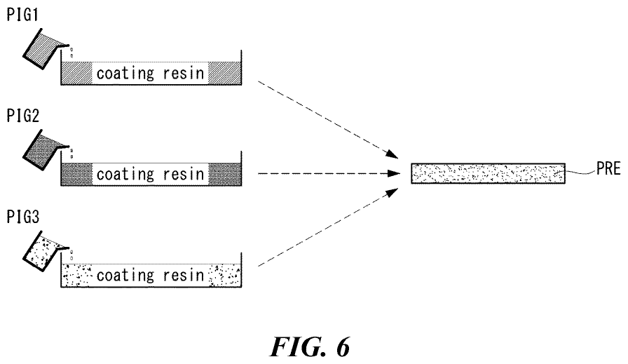

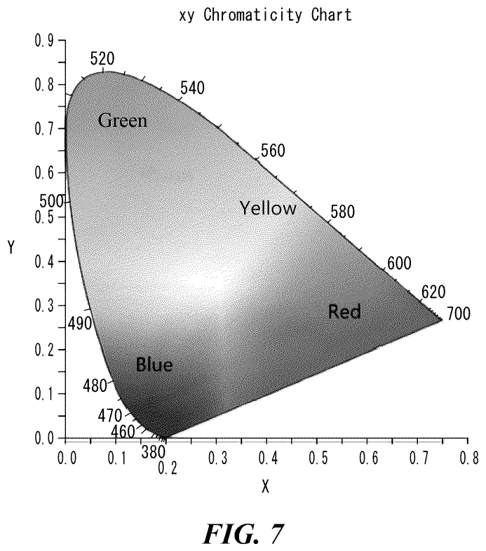

FIG. 6 is a view illustrating a method of configuring the color control layer, and FIG. 7 is a view illustrating a color coordinate control method using the color control layer.

As shown in FIG. 6, the color control layer PRE may be formed by adding a selected pigment to a resin that can be manufactured using a coating method (a coating resin) and then blending the same. In this case, the pigment may include a first pigment PIG1 to a third pigment PIG3 capable of representing a first color to a third color, respectively. However, the pigment that can be included in the color control layer PRE is not limited thereto.

As shown in FIGS. 6 and 7, a specific color pigment may be added to the color control layer PRE in order to control color coordinates based on values visible on an xy chromaticity chart.

As a first example, if the display panel layer PNL appears reddish, the color control layer PRE may include a green-based pigment in order to correct the color tone of the display panel layer PNL. As a second example, if the display panel layer PNL appears greenish, the color control layer PRE may include a red-based pigment in order to correct the color tone of the display panel layer PNL. As a third example, if the display panel layer PNL appears bluish, the color control layer PRE may include a yellow-based pigment in order to correct the color tone of the display panel layer PNL.

Thus, the color control layer PRE may include a complementary color pigment opposite (or approximately opposite) the color visible on the display panel layer PNL. Therefore, the pigment that can be included in the color control layer PRE may be one selected from among various colors in response to the target color coordinates of the display panel layer PNL (or based on the color on the display panel layer PNL).

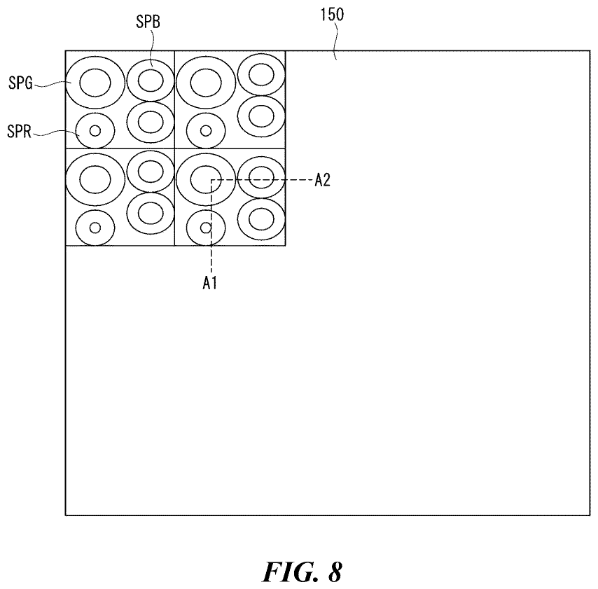

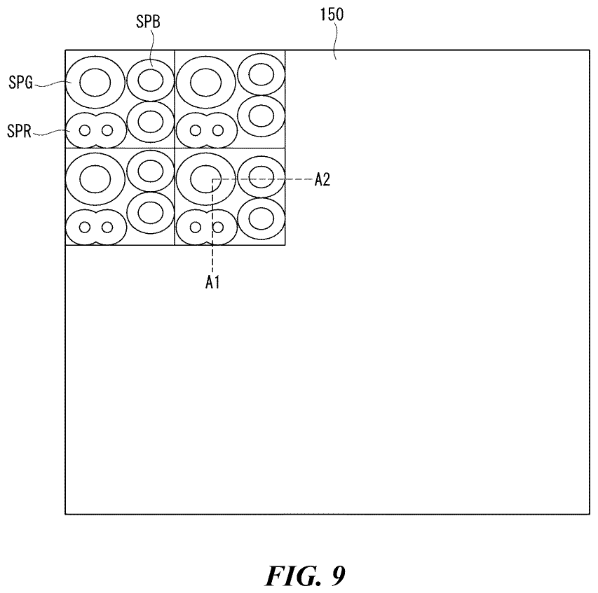

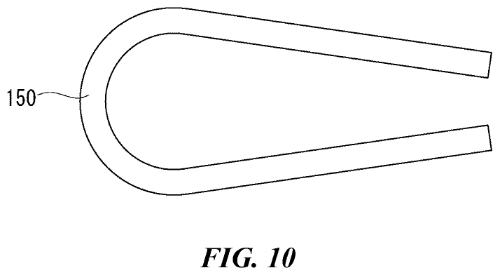

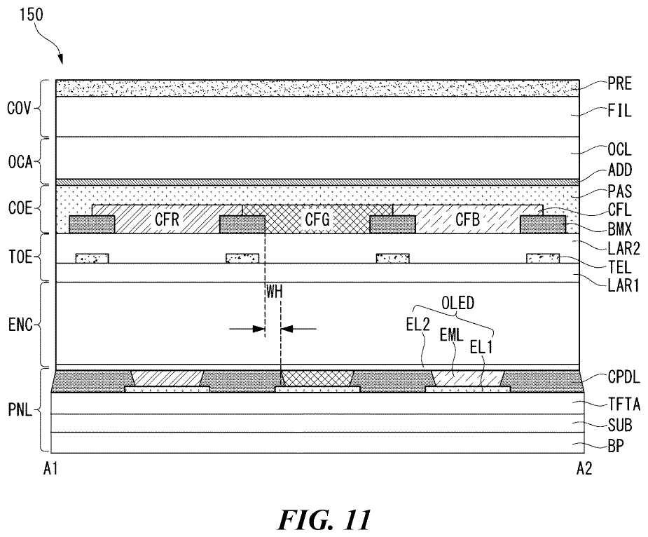

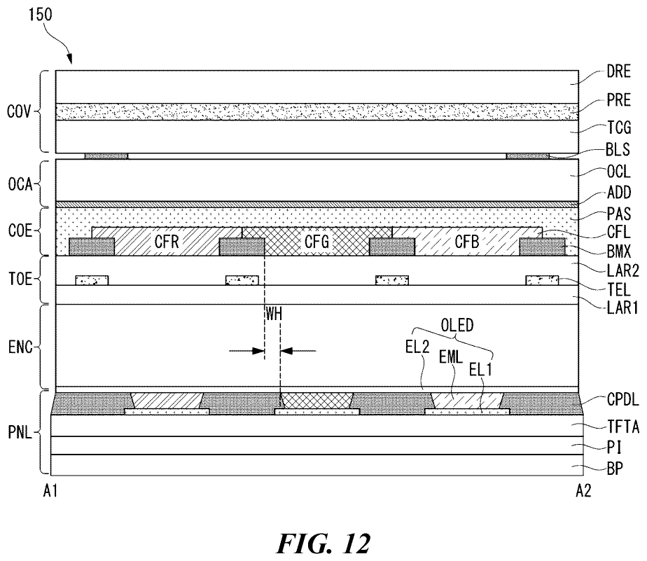

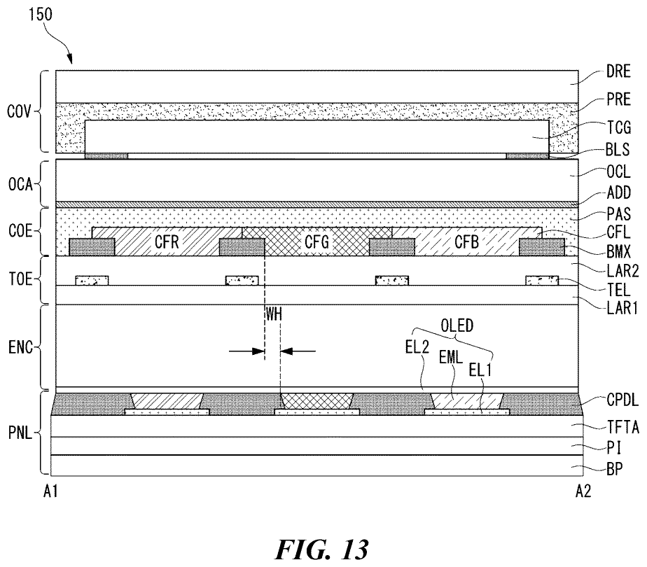

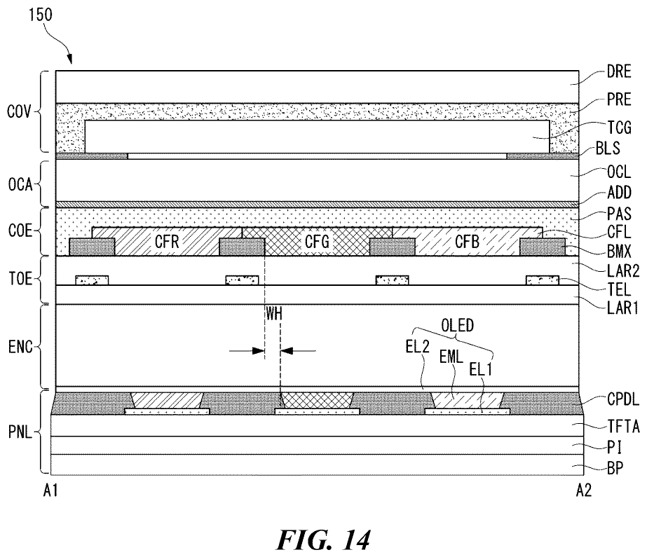

FIG. 8 is a first example view showing the pixel structure of a display panel according to a second embodiment, FIG. 9 is a second example view showing the pixel structure of the display panel according to the second embodiment, FIG. 10 is an example view showing the physical characteristics of the display panel shown in FIG. 8, FIG. 11 is a sectional view taken along line A1-A2 of FIG. 8 according to a first example, FIG. 12 is a sectional view taken along line A1-A2 of FIG. 8 according to a second example, FIG. 13 is a sectional view taken along line A1-A2 of FIG. 8 according to a third example, and FIG. 14 is a sectional view taken along line A1-A2 of FIG. 8 according to a fourth example. Meanwhile, the sectional view taken along line A1-A2 of FIG. 9 may be similar or identical to FIGS. 11, 12, and 13, and reference is made thereto.

As shown in FIGS. 8 and 9, according to the second embodiment, the display panel 150 may include a red subpixel SPR, a green subpixel SPG, and a blue subpixel SPB. For example, the red subpixel SPR, the green subpixel SPG, and the blue subpixel SPB may each include an opening (or an emission portion) defining a light emitting area, and at least one thereof may be implemented so as to have a different size.

The opening (or the emission portion) defining the light emitting area in each of the red subpixel SPR, the green subpixel SPG, and the blue subpixel SPB may include one circle, as shown in FIG. 8, or may include two circles, as shown in FIG. 9.

However, the opening (or the emission portion) may have a polygonal or oval shape, and at least one of the red subpixel SPR, the green subpixel SPG, and the blue subpixel SPB may be implemented so as to have a different shape.

As shown in FIG. 10, according to the second embodiment, the display panel 150 may have a foldable physical characteristic that allows bending of a part thereof. For example, depending on the material and thickness of the cover layer, the display panel 150 may have a physical characteristic that allows bending of a part thereof to a level of 1.34R to 3.52R. In addition, according to the second embodiment, the display panel 150 may not include a polarizer typically used to enhance the foldable physical characteristic.

Since the display panel 150 having the foldable physical characteristic does not include a polarizer, optical response may be difficult if the color tone (hue) of the display panel layer PNL shifts to one side due to the structural characteristics of the subpixels, compared to a display panel including a polarizer.

However, the display panel 150 according to the second embodiment may remedy the problem (e.g., off-state appearance of the display) arising from color tone (hue) shift in the display panel layer PNL based on the color control layer included in the cover layer. The relevant structure will be described below.

As shown in FIGS. 11 to 14, according to the second embodiment, the display panel 150 may include a display panel layer PNL, an encapsulation layer ENC, a touch electrode layer TOE, a color filter layer COE, an optically clear adhesive layer OCA, and a cover layer COV. The display panel layer PNL, the encapsulation layer ENC, the touch electrode layer TOE, the color filter layer COE, and the optically clear adhesive layer OCA may be implemented as follows.

The display panel layer PNL may include a backplate layer BP, a substrate layer SUB, a transistor layer TFTA, a bank layer CPDL, and a light emitting diode layer OLED. For example, the substrate layer SUB may be located on the backplate layer BP, the transistor layer TFTA may be located on the substrate layer SUB, the bank layer CPDL may be located on the transistor layer TFTA, and the light emitting diode layer OLED may be located in an opening partitioned by the bank layer CPDL. The bank layer CPDL may include a black pigment configured to prevent or minimize light leakage between adjacent openings; however, the present disclosure is not limited thereto.

The backplate layer BP may be made of a material capable of enhancing the physical rigidity of the substrate layer SUB. The substrate layer SUB may be made of a film capable of bending the display panel layer PNL. The transistor layer TFTA may include a transistor(s) and a capacitor capable of driving a light emitting diode included in the light emitting diode layer OLED. The light emitting diode layer OLED may include a first electrode layer EL1, an emission layer EML, and a second electrode layer EL2, which may be formed so as to be divided into a red emission layer, a green emission layer, and a blue emission layer in response to the positions of the subpixels.

The encapsulation layer ENC may be located on the display panel layer PNL. The encapsulation layer ENC may be made of a material capable of protecting the transistor layer TFTA and the light emitting diode layer OLED located on the display panel layer PNL from external air. For example, the encapsulation layer ENC may be implemented as at least one of an organic layer and an inorganic layer or a composite layer in which organic and inorganic layers are alternately stacked.

The touch electrode layer TOE may be located on the encapsulation layer ENC. The touch electrode layer TOE may be implemented as a touch sensor capable of receiving user touch input. The touch sensor may include a self-capacitive touch sensor or a mutual-capacitive touch sensor. For example, the touch electrode layer TOE may include a first touch protection layer LAR1 located on the encapsulation layer ENC, a touch electrode layer TEL located on the first touch protection layer LAR1, and a second touch protection layer LAR2 located on the touch electrode layer TEL. The touch electrode layer TEL is shown as a single layer corresponding to the bank layer CPDL, but touch electrode layer may also have a multilayer structure depending on a touch sensing mode.

The color filter layer COE may be located on the touch electrode layer TOE. The color filter layer COE may be made of a material capable of converting light emitted from the light emitting diode layer OLED. For example, the color filter layer COE may include a black matrix layer BMX located on the second touch protection layer LAR2, red, green, and blue color filters CFR, CFG, and CFB partitioned by the black matrix layer BMX, and a passivation layer PAS located on the color filters CFR, CFG, and CFB. The black matrix layer BMX may be located so as to correspond to the bank layer CPDL and may be implemented as a structure having a smaller width than the bank layer CPDL (a “BMX pull back” structure where a side surface of the bank layer is pulled back by an area corresponding to WH); however, the present disclosure is not limited thereto.

The optically clear adhesive layer OCA may be located on the color filter layer COE. The optically clear adhesive layer OCA may be made of a high-transmittance (or high-light-transmission) optical adhesive. For example, the optically clear adhesive layer OCA may include an adhesive layer ADD located on the passivation layer PAS and an optical layer OCL located on the adhesive layer ADD.

Meanwhile, according to the second embodiment, the cover layer COV may vary as shown in FIGS. 11 to 14, which will be described as follows.

As shown in FIG. 11, the cover layer COV may include a film layer FIL and a color control layer PRE. For example, the edges of the film layer FIL and the color control layer PRE may be located so as to correspond to the edges of the display panel layer PNL, the encapsulation layer ENC, the touch electrode layer TOE, the color filter layer COE, and the optically clear adhesive layer OCA.

A structure like the first example may facilitate thinning by forming the cover layer COV based on the film layer FIL, and may easily control/tune problems arising from the color tone (hue) of the display panel layer PNL shifting in one direction based on the color control layer PRE.

As shown in FIG. 12, the cover layer COV may include a black frame layer BLS, a glass layer TCG, a color control layer PRE, and a resin layer DRE. For example, the edges of the glass layer TCG, the color control layer PRE, and the resin layer DRE may be located so as to correspond to the edges of the display panel layer PNL, the encapsulation layer ENC, the touch electrode layer TOE, the color filter layer COE, and the optically clear adhesive layer OCA.

The black frame layer BLS may be located between the optical layer OCL and the glass layer TCG. The black frame layer BLS may include a black color (or a black pigment) to prevent or minimize light leakage at the edges of the display panel layer PNL. For example, the black frame layer BLS may have a frame shape that exposes the active area AA (see FIG. 3) from the display panel layer PNL. To this end, the black frame layer BLS may have an area overlapping the black matrix layer BMX located adjacent to the edge of the color filter layer COE.

In the structure like the second example, since the cover layer COV is formed based on the glass layer TCG, it is possible to enhance transparency and strength. In addition, it is possible to easily control/tune problems arising from the color tone (hue) of the display panel layer PNL shifting in one direction based on the color control layer PRE.

As shown in FIG. 13, the cover layer COV may include a black frame layer BLS, a glass layer TCG, a color control layer PRE, and a resin layer DRE. For example, the edges of the color control layer PRE and the resin layer DRE may be located so as to correspond to the edges of the display panel layer PNL, the encapsulation layer ENC, the touch electrode layer TOE, the color filter layer COE, and the optically clear adhesive layer OCA.

The glass layer TCG may have a smaller area than the color control layer PRE and the resin layer DRE. Accordingly, the color control layer PRE may be formed so as to cover an upper surface and a side surface of the glass layer TCG. In the structure shown in FIG. 13, it is possible not only to prevent or minimize light leakage at the edges of the display panel layer PNL but also to minimize surface delamination that may occur at the edges of the glass layer TCG and the color control layer PRE due to stress generated when bending a part of the display panel 150.

The black frame layer BLS may have a frame shape that exposes only the active area AA (see FIG. 3) from the display panel layer PNL. The black frame layer BLS may have an area overlapping the black matrix layer BMX located adjacent to the edge of the color filter layer COE, and may be located so as to correspond to the edge of the glass layer TCG.

In the structure like the third example, it is possible to minimize surface delamination between the glass layer TCG and the color control layer PRE when forming the cover layer COV based on the glass layer TCG and to easily control/tune problems arising from the color tone (hue) of the display panel layer PNL shifting in one direction based on the color control layer PRE. Furthermore, in the structure like the third example, it is possible to prevent or minimize light leakage at the edge of the display panel layer PNL based on the black frame layer BLS.

As shown in FIG. 14, the cover layer COV may include a black frame layer BLS, a glass layer TCG, a color control layer PRE, and a resin layer DRE. The structure shown in FIG. 14 is similar to that shown in FIG. 13, but the black frame layer BLS may extend and be located so as to correspond to the edges of the display panel layer PNL, the encapsulation layer ENC, the touch electrode layer TOE, the color filter layer COE, and the optically clear adhesive layer OCA. In other words, the black frame layer BLS may have an area contacting both the edge of the glass layer TCG and the edge of the color control layer PRE.

In the structure like the fourth example, it is possible to minimize surface delamination between the glass layer TCG and the color control layer PRE when forming the cover layer COV based on the glass layer TCG and to easily control/tune problems arising from the color tone (hue) of the display panel layer PNL shifting in one direction based on the color control layer PRE. Furthermore, in the structure like the fourth example, it is possible to prevent or minimize light leakage at the edge of the display panel layer PNL based on the black frame layer BLS.

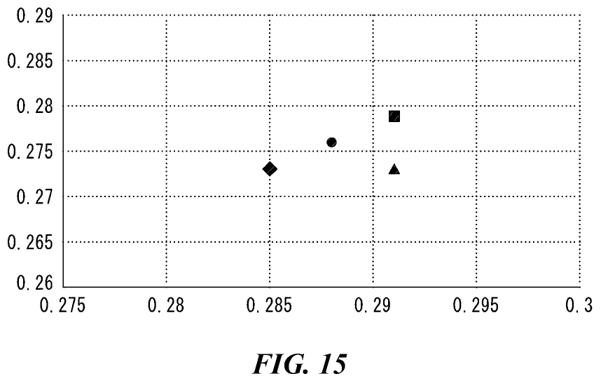

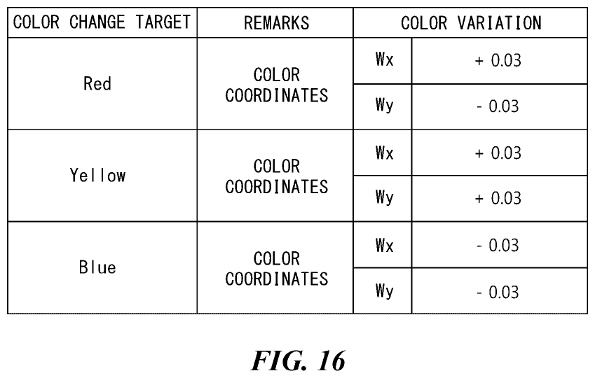

FIG. 15 is an example view showing the color coordinates of a cover layer including a color control layer, and FIG. 16 is an example view showing the color coordinates of a cover layer including a color control layer.

In FIG. 15, a circular shape corresponds to reference color coordinates, and square, triangle, and rhombus shapes represent, in a 1931 CIE color coordinate system, data obtained by placing a cover layer including three color-specific color control layers on a light source of specific brightness and taking a photograph using an optical system. Here, the square shape is color coordinates for yellow, the triangle shape is color coordinates for red, and the rhombus shape is color coordinates for blue.

As can be seen from FIG. 16, the cover layer including the three color-specific color control layers may have a certain level of color variation (see the color tuning variation in FIG. 16) relative to the reference color coordinates (see the circle shape in FIG. 15). Meanwhile, FIGS. 15 and 16 should be understood as reference details when implementing the cover layer including the color control layer.

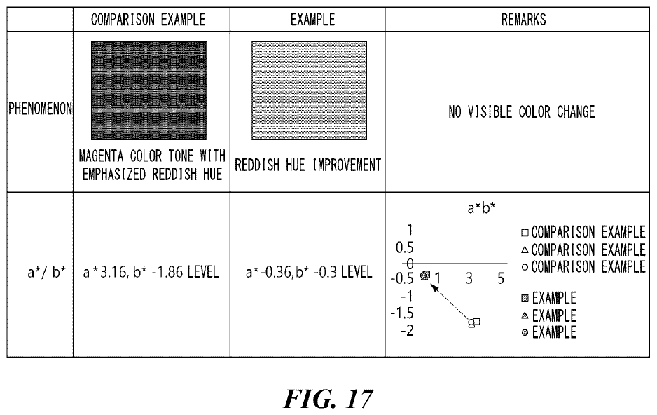

FIG. 17 is a view showing a display panel layer according to a comparative example and a display panel layer according to an example for comparison. In FIG. 17, the comparative example and the example represent the level of a reddish color tone in a CIE L*a*b* color space, and the remarks in FIG. 17 indicate that the cover layer including the color control layer was applied to three comparative examples, achieving improvements as in three examples. Meanwhile, note that the display panel layer according to the comparative example and the display panel layer according to the example are implemented based on the same configuration, differing only in whether the cover layer includes a color control layer.

As shown in FIG. 17, the display panel layer according to the comparative example exhibits a magenta color tone level with emphasized reddish hue (see “a*3.16 and b*−1.86” shown in the comparative example of FIG. 17 and the graph in the remarks), but no color control layer is included in the cover layer, which may make it difficult to improve the color tone. For example, when a* is 3.16, indicating a reddish color tone, and b* is −1.86, indicating a bluish color tone, as in the comparative example of FIG. 17, the problem of appearing as magenta with emphasized reddish hue (a mixture of red and blue) may occur.

The display panel layer according to the example also exhibits a reddish color tone due to the level corresponding to that of the comparative example. However, it is possible to readily remedy the problem of the color tone appearance by controlling the color tone level of the comparative example (a*3.16 and b*−1.86) based on the color control layer included in the cover layer to the color tone level of the example (see “a*−3.16 and b*−0.3” shown in the comparative example of FIG. 17 and the graph in the remarks). For example, in the case like the comparative example of FIG. 17, a green pigment to shift a* in the −direction and a yellow pigment to shift b* in the +direction may be blended to move a* and b* toward the center value.

Meanwhile, as can be seen from the remarks, no apparent color change was observed even when the color control layer is included in the cover layer. In the remarks, a* represents the horizontal axis, and b* represents the vertical axis.

As is apparent from the above description, the present disclosure has the effect that it is possible to remedy the problems arising from the color tone (hue) of a display panel layer shifting in one direction. In addition, the present disclosure has the effect that it is possible to easily control/tune the target color coordinates of the display panel layer even when a polarizer is not included. Furthermore, the present disclosure has the effect that it is possible not only to prevent or minimize light leakage at the edges of layers constituting a display panel but also to minimize surface delamination that may occur at the edges of the layers constituting the display panel.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a display panel layer configured to display an image; and
a cover layer located on the display panel layer,
wherein the cover layer comprises a color control layer having a color other than clear or transparent, the color control layer configured to control a color tone appearing on the display panel layer.

2. The display device according to claim 1, wherein the color control layer comprises a pigment exhibiting a second color different from a first color corresponding to the color tone.

3. The display device according to claim 1, wherein the color control layer comprises a resin and a pigment.

4. The display device according to claim 1, wherein the cover layer comprises:
a film layer located on the display panel layer; and
the color control layer located on the film layer.

5. The display device according to claim 1, wherein the cover layer comprises:
a glass layer located on the display panel layer;
the color control layer located on the glass layer; and
a resin layer located on the color control layer.

6. The display device according to claim 5, wherein the glass layer has a smaller area than the color control layer.

7. The display device according to claim 6, wherein the color control layer covers an upper surface and a side surface of the glass layer.

8. The display device according to claim 5, wherein the cover layer further comprises a black frame layer located between the display panel layer and the glass layer, the black frame layer having a frame shape that exposes an active area of the display panel layer.

9. The display device according to claim 1, wherein the display panel layer comprises a subpixel having at least one of a circular opening, an oval opening, and a polygonal opening.

10. The display device according to claim 1, wherein the color control layer has a color for controlling the color tone appearing on the display panel layer in a display off state.

11. A display device comprising:
a display panel layer configured to display an image; and
a cover layer located on the display panel layer,
wherein the color control layer comprises a resin and a pigment.

12. The display device according to claim 11, wherein the pigment is composed of a second color different from a first color appearing on the display panel layer.

13. The display device according to claim 11, wherein the color control layer has a color for controlling the color tone appearing on the display panel layer in a display off state.

14. A method of manufacturing a display device, the method comprising:
forming a display panel layer configured to display an image;
forming a color control layer having a color for controlling a color tone appearing on the display panel layer; and
forming a cover layer comprising the color control layer on the display panel layer.

15. The method according to claim 14, wherein forming the color control layer comprises forming the color control layer with a pigment exhibiting a second color different from a first color corresponding to the color tone.

16. The method according to claim 14, wherein forming the color control layer comprises adding a material that exhibits a color to a resins.
